(19) United States
(12) Patent Application Publication
(10) Pub. No.: US 2024/0040691 A1
(43) Pub. Date: Feb. 1, 2024

(54) PRINTED CIRCUIT BOARD AND METHOD FOR MANUFACTURING THE SAME

(71) Applicant: SAMSUNG ELECTRO-MECHANICS CO., LTD., Suwon-si (KR)

(72) Inventor: Kwon Su YUN, Suwon-si (KR)

(73) Assignee: SAMSUNG ELECTRO-MECHANICS CO., LTD., Suwon-si (KR)

(21) Appl. No.: 18/212,863

(22) Filed: Jun. 22, 2023

(30) Foreign Application Priority Data
Jul. 28, 2022 (KR) 10-2022-0093704

(51) Int. Cl. H05K 1/02; H05K 1/11; H05K 3/02

(52) U.S. Cl. CPC H05K 1/0296; H05K 1/115; H05K 3/02; H05K 2201/10984; H05K 2201/10242; H05K 2201/10674

(57) ABSTRACT

A printed circuit board (PCB) includes an insulating layer, a first solder resist layer disposed on an upper surface of the insulating layer, a first conductive pattern disposed on the insulating layer and providing a conductive post protruding from an upper surface of the first solder resist layer, and a second conductive pattern buried in the insulating layer and having an upper surface positioned to be lower than the upper surface of the insulating layer.

### CROSS-REFERENCE TO RELATED APPLICATION

This application claims benefit of priority to Korean Patent Application No. 10-2022-0093704 filed on Jul. 28, 2022 in the Korean Intellectual Property Office, the disclosure of which is incorporated herein by reference in its entirety.

### TECHNICAL FIELD

The present disclosure relates to a printed circuit board (PCB) and a method for manufacturing the PCB.

### BACKGROUND

According to the high performance and/or super-integration of electronic or electric devices in which PCBs may be used, the size of the components of PCBs has also gradually decreased. As the PCB itself or components of PCBs is highly integrated and/or miniaturized, the difficulty in securing the reliability of PCBs may increase.

In addition, as the performance of semiconductor chips (e.g., processors, memories) has gradually increased, the degree of integration of semiconductor chips has also gradually increased and a spacing between input/output (I/O) terminals of semiconductor chips and the size of each of the I/O terminals has also gradually decreased. As a result, the degree of integration and the difficulty of forming an electrical connection path that PCBs may provide has also gradually increased.

Recently, PCBs have been increasingly widely used in devices requiring a large electrical connection path, such as installed electronic devices (including servers) or electric devices (including vehicles). PCBs used in these devices may have a large horizontal area or a large number of conductive layers, and the difficulty of securing the reliability of an electrical connection path that PCBs may provide has also gradually increased.

### SUMMARY

An aspect of the present disclosure may provide a printed circuit board (PCB) and a method for manufacturing the same.

According to an aspect of the present disclosure, a printed circuit board (PCB) may include an insulating layer; a first solder resist layer disposed on an upper surface of the insulating layer; a first conductive pattern disposed on the insulating layer and providing a conductive post protruding from an upper surface of the first solder resist layer; and a second conductive pattern buried in the insulating layer and having an upper surface positioned to be lower than the upper surface of the insulating layer.

According to another aspect of the present disclosure, a printed circuit board (PCB) may include an insulating layer; a first solder resist layer disposed on an upper surface of the insulating layer; a first conductive pattern buried in the insulating layer; and a conductive post disposed on an upper surface of the first conductive pattern and protruding from an upper surface of the first solder resist layer, wherein an edge of the upper surface of the first conductive pattern is positioned to be lower than the upper surface of the insulating layer.

According to another aspect of the present disclosure, a method for manufacturing a printed circuit board (PCB) may include: forming first and second conductive patterns on a first conductive layer on a base insulating layer; forming an insulating layer on the first and second conductive patterns; separating the base insulating layer from at least a portion of the first conductive layer; etching a partial region of at least a portion of the first conductive layer to form a conductive post; forming a first solder resist layer on a surface of the insulating layer on which the conductive post is formed; and etching a portion of the first solder resist layer to reduce a thickness of the first solder resist layer.

According to another aspect of the present disclosure, a printed circuit board (PCB) may include an insulating layer; a first conductive pattern buried in the insulating layer; and a second conductive pattern buried in the insulating layer and having an upper surface positioned to be lower than an upper surface of the insulating layer; a first solder resist layer disposed on the insulating layer to cover the second conductive pattern; and a conductive post extending from the first conductive pattern to protrude from an upper surface of the first solder resist layer.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1A to 1L are side views illustrating a process of manufacturing a printed circuit board (PCB) according to a method for manufacturing a PCB according to an exemplary embodiment in the present disclosure;

FIG. 1M is a side view illustrating a PCB according to an exemplary embodiment in the present disclosure;

FIG. 1N is a side view illustrating that a conductive post of a PCB is electrically connected to a semiconductor chip in a flip-chip structure according to an exemplary embodiment in the present disclosure;

FIGS. 2A and 2B are side views illustrating a structure in which a conductive post and a first solder resist layer of a PCB are spaced apart from each other according to an exemplary embodiment in the present disclosure;

FIGS. 3A and 3B are side views illustrating a structure in which a thickness of the second conductive pattern is adjusted by a method for manufacturing a PCB according to an exemplary embodiment in the present disclosure;

FIGS. 4A to 4C are side views illustrating formation of a conductive post without an etch stop pattern in a method for manufacturing a PCB according to an exemplary embodiment in the present disclosure;

FIGS. 5A and 5B are side views illustrating a structure in which the number of insulating layers is adjusted by a method for manufacturing a PCB according to an exemplary embodiment in the present disclosure;

FIG. 6 is a side view illustrating a structure in which an edge of an upper surface of a first conductive pattern of a PCB is positioned to be lower than an upper surface of an insulating layer according to an exemplary embodiment in the present disclosure;

FIG. 7 is a plan view illustrating first and second conductive patterns of a PCB according to an exemplary embodiment in the present disclosure;

FIG. 8A is a diagram illustrating a structure of an electronic device in which a PCB may be disposed according to an exemplary embodiment in the present disclosure; and

FIG. 8B is a diagram illustrating a system of an electronic device in which a PCB may be disposed according to an exemplary embodiment in the present disclosure.

### DETAILED DESCRIPTION

Exemplary embodiments of the present disclosure will now be described in detail with reference to the accompanying drawings.

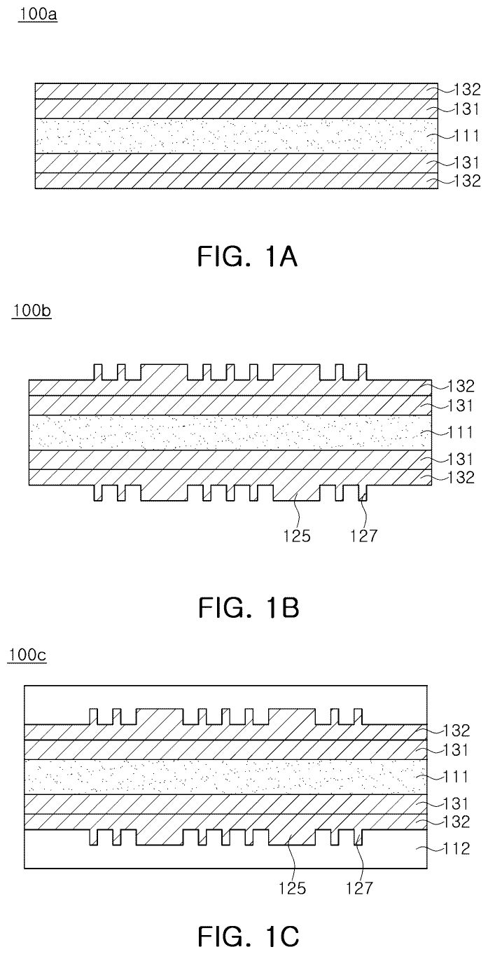

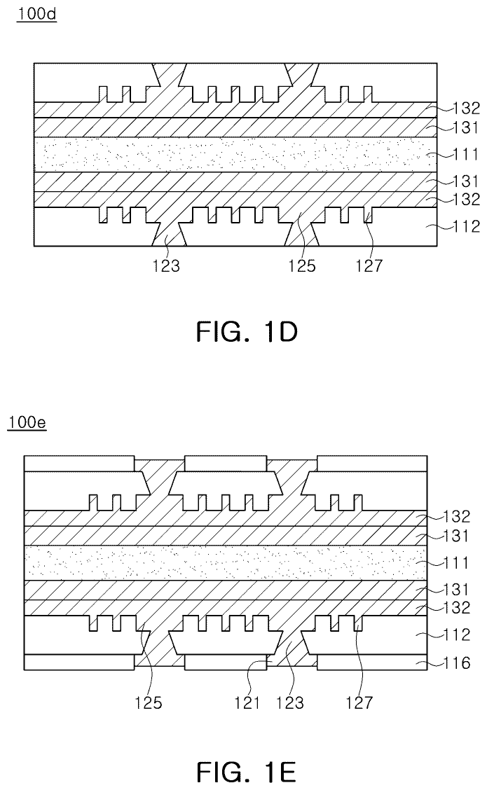

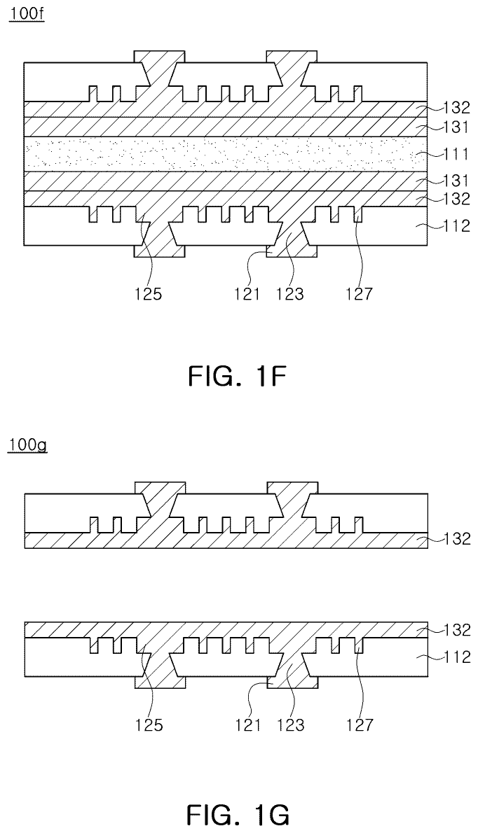

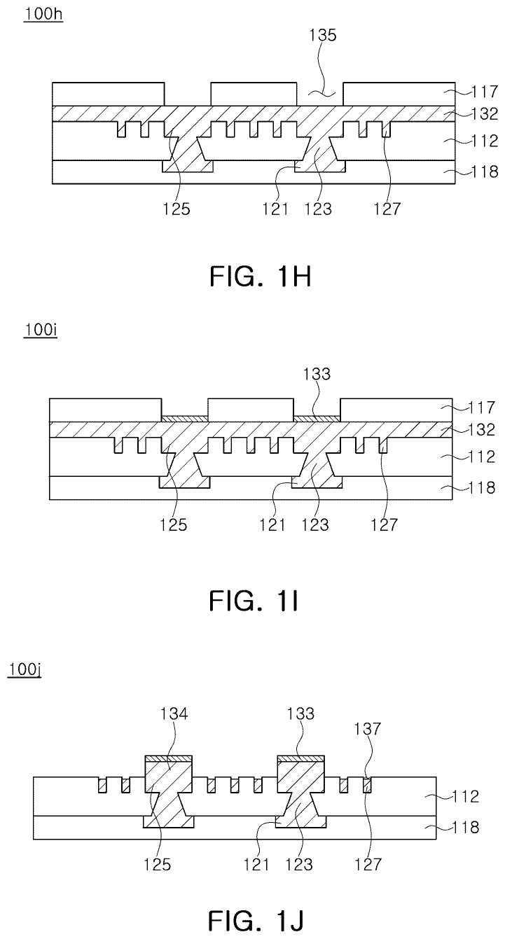

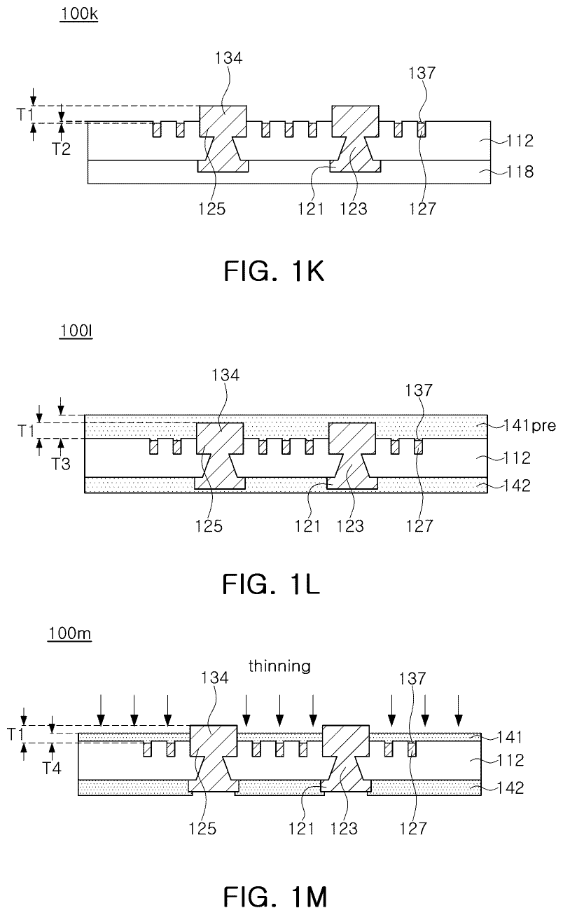

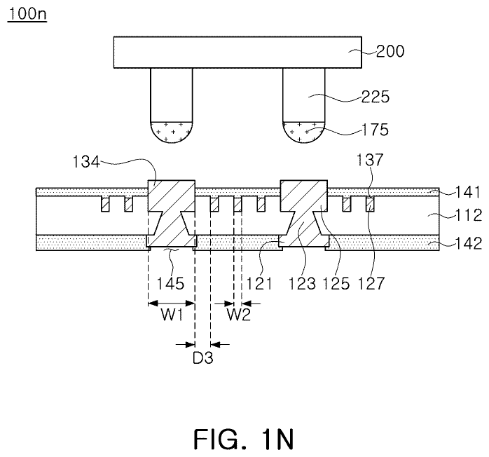

Referring to FIGS. 1A and 1B, a method for manufacturing a printed circuit board (PCB) according to an exemplary embodiment in the present disclosure may include forming a first conductive pattern 125 and a second conductive pattern 127 on first conductive layers 131 and 132 on a base insulating layer 111.

For example, a combined structure of the base insulating layer 111 and the first conductive layers 131 and 132 of unfinished PCBs 100a and 100b may be a copper clad laminate (CCL), and thus, at least a portion 132 of the first conductive layers 131 and 132 may include copper (Cu). For example, in the first conductive layers 131 and 132, the portion 131 in contact with the base insulating layer 111 may be replaced with an adhesive layer, and thus, the combined structure of the base insulating layer 111 and the first conductive layers 131 and 132 may be manufactured according to a detachable copper foil (DCF) method.

For example, the first and second conductive patterns 125 and 127 may be a portion of a plating layer formed according to a copper (Cu) plating process, and may be formed by exposure and development in a state in which a protective pattern is formed on the plating layer.

Referring to FIGS. 1C to 1E, the method for manufacturing a PCB according to an exemplary embodiment in the present disclosure may include forming an insulating layer 112 on the first and second conductive patterns 125 and 127.

For example, the insulating layer 112 of unfinished PCBs 100c, 100d, and 100e may be a copper clad laminate (CCL), ABF, prepreg, FR-4, bismaleimide triazine (BT), a photoimageable dielectric (PID) resin, and may be at least one selected from the group consisting of a thermosetting resin, such as an epoxy resin, a thermoplastic resin, such as polyimide, and polytetrafluoroethylene (PTFE), glass-based, and ceramic-based (e.g., low temperature co-fired (LTCC) resin. In one example, the first conductive pattern 125 and the second conductive pattern 127 may be buried in the insulating layer 112 at substantially a same depth. The meaning of the term “substantially” may include a process error occurring in the manufacturing process, a measurement error, or the like, recognizable by one of ordinary skill in the art. For example, the configuration in which elements have substantially the same depth may include the example in which the elements have exactly the same depth, and also the example in which a minute difference in depth may exist due to a process error occurring in the manufacturing process, a measurement error, or the like, recognizable by one of ordinary skill in the art.

For example, a portion of the insulating layer 112 may be drilled by a laser or drilling, and a conductive via 123 may fill a drilled space of the insulating layer 112. A third conductive pattern 121 may be formed on one surface of the insulating layer 112, and may be formed by exposure and development in a state in which a protective pattern 116 is formed in a manner similar to that in which the first and second conductive patterns 125 and 127 are formed. Thereafter, the protective pattern 116 may be etched.

For example, a material that may be included in the first and second conductive patterns 125 and 127 and the conductive via 123 may be at least one of copper (Cu), silver (Ag), palladium (Pd), aluminum (Al), nickel (Ni), titanium (Ti), gold (Au), and platinum (Pt). For example, the third conductive pattern 121 may be implemented using a semi-additive process (SAP), a modified semi-additive process (MSAP), or a subtractive method.

Referring to FIGS. 1F and 1G, the method for manufacturing a PCB according to an exemplary embodiment in the present disclosure may include separating the base insulating layer 111 from at least a portion 132 of the first conductive layer.

For example, upper and lower structures of the base insulating layer 111 in unfinished PCBs 100f and 100g may be used to manufacture a plurality of PCBs. Since the base insulating layer 111 may be a core, each of the plurality of PCBs may have a coreless structure.

Referring to FIGS. 1H to 1K, the method for manufacturing a PCB according to an exemplary embodiment in the present disclosure may include forming a conductive post 134 by etching a partial region of at least a portion 132 of the first conductive layer.

For example, the method for manufacturing a PCB according to an exemplary embodiment in the present disclosure may further include forming an etch stop pattern 133 in a region of the first conductive layer 132 overlapping the first conductive pattern between the separating of the base insulating layer and the forming of the conductive post 134 and removing the etch stop pattern 133 between the forming of the conductive post 134 and the forming of a first solder resist layer. For example, the etch stop pattern 133 may include at least one of nickel (Ni) and tin (Sn).

For example, in an unfinished PCB 100h, the protective pattern 117 may be formed in a region in which the etch stop pattern 133 is not formed on one surface of the first conductive layer 132, so that the protective pattern 117 may have a temporary opening 135. An unfinished PCB 100i may include the etch stop pattern 133 disposed in the temporary opening 135.

A portion of the protective pattern 117 and the first conductive layer 132 that does not vertically overlap the etch stop pattern 133 may be etched. Accordingly, an unfinished PCB 100j may include a conductive post 134 vertically overlapping the etch stop pattern 133. The forming of the conductive post 134 may include forming the conductive posts 134 on an upper surface of the first conductive pattern 125. In one example, a side surface of the conductive post 134 may have a substantially constant slope with respect to the upper surface of the insulating layer 112. The configuration in which the side surface of the conductive post 134 may have a substantially constant slope with respect to the upper surface of the insulating layer 112 may include the example in which the side surface of the conductive post 134 may have a constant slope with respect to the upper surface of the insulating layer 112, and also the example in which a minute deviation in slope may exist due to a process error occurring in the manufacturing process, a measurement error, or the like, recognizable by one of ordinary skill in the art.

Since the conductive post 134 may be formed from the first conductive layer 132, uniformity of a thickness T1 of the conductive post 134 may be affected by uniformity of a thickness of the first conductive layer 132. Since the first conductive layer 132 may have wide, simple, and smooth upper and lower surfaces, the uniformity of the thickness of the first conductive layer 132 may increase. Accordingly, the uniformity of the thickness T1 of the conductive post 134 may increase. As the uniformity of the thickness T1 increases, when the number of the conductive posts 134 is plural, a thickness difference between the thickest conductive post and the thinnest conductive post, among the plurality of conductive posts 134, may be reduced.

In other words, in the process of forming the conductive post 134, a difference between the design and the reality (process dispersion) may be small, so that the possibility of an occurrence of an electrical short between the conductive post 134 and the adjacent conductive structure (e.g., the second conductive pattern 127) may be reduced.

Since a partial region of the first conductive layer 132 may vertically overlap the second conductive pattern 127, a portion of the second conductive pattern 127 may also be etched according to an etching process method or time adjustment. Accordingly, the upper surface of the second conductive pattern 127 may be positioned to be lower than an upper surface of the insulating layer 112, and a recessed portion 137 may be provided.

Accordingly, the possibility that a metal material corresponding to the first conductive layer 132 remains between the conductive post 134 and the second conductive pattern 127 in a partial region of the first conductive layer 132 may be reduced, and thus, the possibility of an unintentional connection between the conductive post 134 and the second conductive pattern 127 or the possibility of an electrical short may be reduced.

An unfinished PCB 100k may have a structure in which the etch stop pattern is removed. For example, the thickness T1 of the conductive post 134 may be thicker than the thickness T2 of the recessed portion 137.

Referring to FIG. 1L, the method for manufacturing a PCB according to an exemplary embodiment in the present disclosure may include forming a first solder resist layer 141pre on a surface of the insulating layer 112 on which the conductive post 134 is formed.

For example, the forming of the first solder resist layer 141pre may include forming the first solder resist layer 141pre to contact the second conductive pattern 127 and further forming a second solder resist layer 142 below the insulating layer 112.

For example, a PCB 1001 may include the first solder resist layer 141pre having a thickness T3 greater than the thickness T1 of the conductive post 134. Between the forming of the first solder resist layer 141pre and the etching of a portion of the first solder resist layer 141pre, an upper surface of the first solder resist layer 141pre may be positioned to be higher than an upper surface of the conductive post 134.

Since the first solder resist layer 141pre may be formed to be relatively thick, adhesion between the first solder resist layer 141pre and the second conductive pattern 127 may increase. Accordingly, the possibility that an electrical short occurs between the second conductive pattern 127 and the conductive post 134 may be reduced.

Accordingly, a distance between the conductive post 134 and the second conductive pattern 127 may be advantageously further reduced and the size of each of the conductive post 134 and the second conductive pattern 127 may be advantageously further reduced, and therefore, the PCB manufactured according to the method for manufacturing a PCB according to an exemplary embodiment in the present disclosure may efficiently increase the degree of integration and/or reliability of an electrical connection path that may be provided and suppress an increase in the incidence of defects due to the increased degree of integration (e.g., an electrical short).

Referring to FIG. 1M, the method for manufacturing a PCB according to an exemplary embodiment in the present disclosure may include etching a portion of the first solder resist layer 141 to reduce the thickness of the first solder resist layer 141.

For example, the etching of a portion of the first solder resist layer 141 may include etching a portion of the first solder resist layer 141 so that a difference between the thicknesses of the first solder resist layer 141 and the second solder resist layer 142 further increases.

For example, a PCB 100m may include the first solder resist layer 141 having a thickness T4 less than the thickness T1 of the conductive posts 134. After the etching of the portion of the first solder resist layer 141, an upper surface of the first solder resist layer 141 may be positioned to be lower than an upper surface of the conductive post 134.

Referring to FIG. 1N, the method for manufacturing a PCB according to an exemplary embodiment in the present disclosure may include mounting a semiconductor chip 200 on the conductive post 134 in a flip-chip structure. Since the conductive posts 134 may protrude from the first solder resist layer 141, the semiconductor chip 200 may be efficiently mounted on the conductive post 134, and the PCB 100n may efficiently increase the degree of integration and/or reliability of an electrical connection path that may be provided.

For example, a plurality of input/output (I/O) terminals 225 of the semiconductor chip 200 may be disposed to correspond to the plurality of conductive posts 134, respectively, and may be connected to and fixed to the conductive posts 134 through solder 175.

Referring to FIGS. 1M and 1N, the PCBs 100m and 100n according to an exemplary embodiment in the present disclosure may include the insulating layer 112, the first solder resist layer 141, the first conductive pattern 125, and the second conductive pattern 127.

The first solder resist layer 141 may be disposed on an upper surface of the insulating layer 112. For example, the first solder resist layer 141 may include a material different from that of the insulating layer 112. The group of materials that may be included in the first solder resist layer 141 or the second solder resist layer 142 may be selected from the group of materials of the insulating layer 112 that may be used as a known solder resist, but is not limited thereto. For example, the thickness T4 of the first solder resist layer 141 may be thinner than the thickness of the second solder resist layer 142.

The first conductive pattern 125 may be disposed on the insulating layer 112 and may provide a conductive post 134 protruding from the upper surface of the first solder resist layer 141. Accordingly, the semiconductor chip 200 may be efficiently mounted on the conductive post 134, and the PCBs 100m and 100n may efficiently increase the degree of integration and/or reliability of the electrical connection path that the PCBs 100m and 100n may provide.

Depending on the design, a surface treatment structure, such as an electroless nickel electroless palladium immersion gold (ENEPIG) structure or an organic solder passivation (OSP) structure may be formed on the upper surface of the conductive post 134, but is not limited thereto.

The second conductive pattern 127 may be embedded in the insulating layer 112 and may have an upper surface positioned to be lower than the upper surface of the insulating layer 112. Accordingly, a possibility that the metal material remains between the conductive post 134 and the second conductive pattern 127 may be reduced, so that a possibility of unintentional connection between the conductive post 134 and the second conductive pattern 127 or a possibility of an electrical short may be reduced.

Therefore, in the PCBs 100m and 100n according to an exemplary embodiment in the present disclosure, a distance between the conductive post 134 and the second conductive pattern 127 may be further advantageously reduced and the size of each of the conductive post 134 and the second conductive pattern 127 may be further advantageously reduced, and the degree of integration and/or reliability of an electrical connection path that may be provided may be effectively increased.

For example, the insulating layer 112 may include the recessed portion 137, and a portion of the first solder resist layer 141 and the second conductive pattern 127 may contact each other in the recessed portion 137. Accordingly, since a portion of the first solder resist layer 141 may further stabilize the upper surface of the second conductive pattern 127, the possibility of an electrical short between the second conductive pattern 127 and the conductive post 134 may be further reduced.

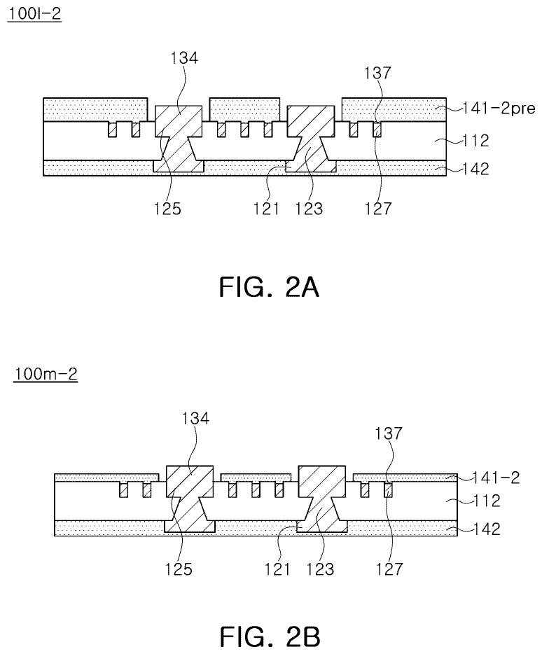

Referring to FIGS. 2A and 2B, first solder resist layers 141-2pre and 141-2 of the PCBs 1001-2 and 100m-2 according to an exemplary embodiment in the present disclosure include an opening in which conductive post 134 is disposed, and a side surface of the conductive post 134 may be spaced apart from the first solder resist layers 141-2pre and 141-2. For example, the PCBs 1001-2 and 100m-2 according to an exemplary embodiment in the present disclosure may advantageously have a non-solder mask defined (NSMD) structure or advantageously have an NSMD structure.

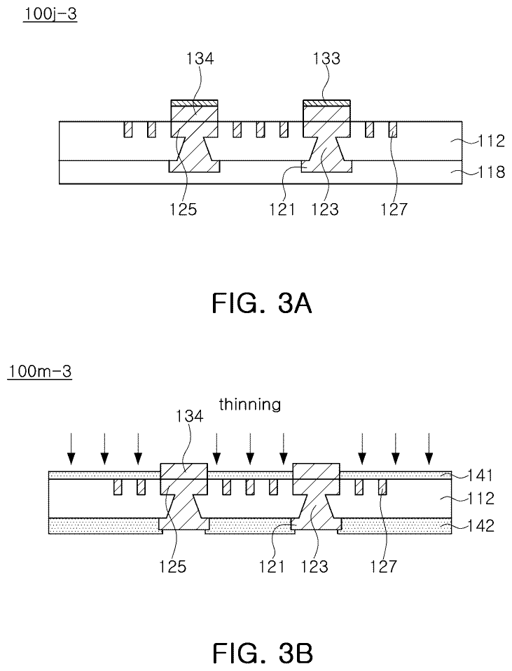

Referring to FIGS. 3A and 3B, in the method for manufacturing a PCB according to an exemplary embodiment in the present disclosure, the process of forming the recessed portions in the PCBs 100j-3 and 100m-3 may be omitted. For example, the structures of the PCBs 100j-3 and 100m-3 may be formed by controlling an etching time or method of a process of etching the first conductive layer on which the conductive post 134 may be based.

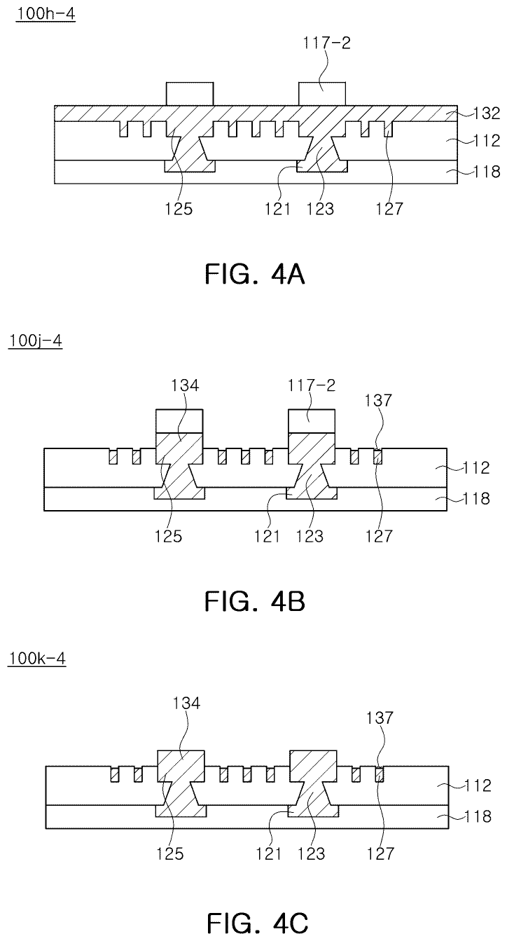

Referring to FIGS. 4A to 4C, in the method for manufacturing a PCB according to an exemplary embodiment in the present disclosure, the process of forming an etch stop pattern on PCBs 100h-4, 100j-4, and 100k-4 may be omitted.

For example, a protective pattern 117-2 may be formed on an upper surface of the first conductive layer 132, and the protective pattern 117-2 may replace the etch stop pattern. In other words, the protective pattern 117-2 may have a structure in which a material of the etch stop pattern is replaced with a photosensitive insulating material from metal.

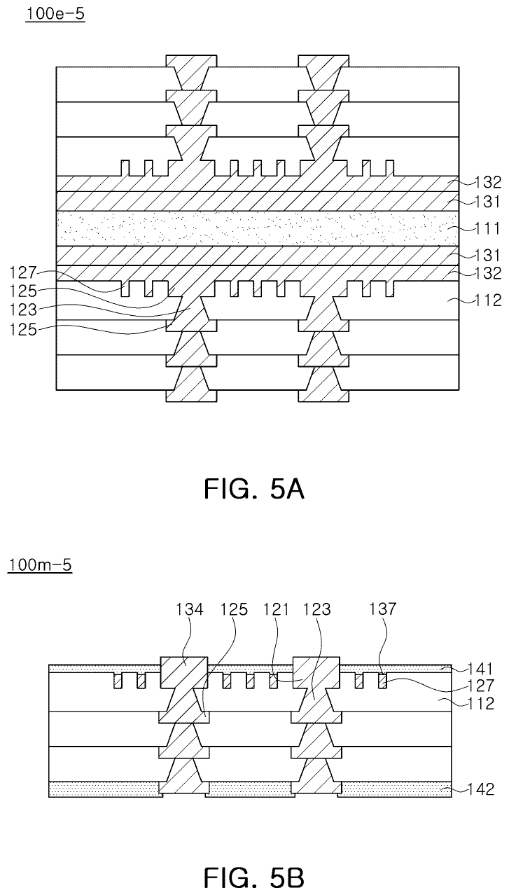

Referring to FIGS. 5A and 5B, the number of each of the insulating layer 112 and the second conductive layer 125 of the PCBs 100e-5 and 100m-5 according to the method for manufacturing a PCB according to an exemplary embodiment in the present disclosure may be plural and the insulating layer 112 and the second conductive layer 125 may be alternately stacked on each other.

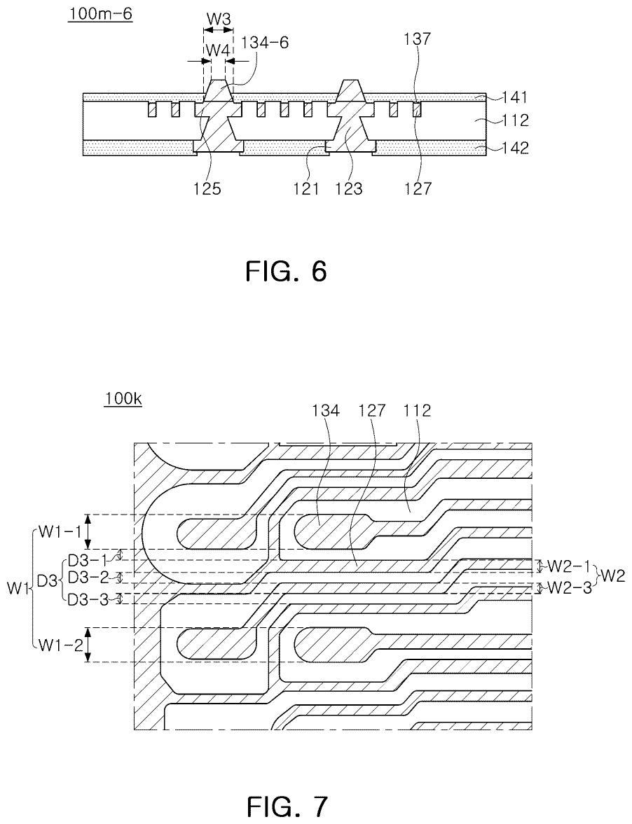

Referring to FIG. 6, a PCB 100m-6 according to an exemplary embodiment in the present disclosure may include the insulating layer 112, the first solder resist layer 141 disposed on an upper surface of the insulating layer 112, the first conductive pattern 125 embedded in the insulating layer, and a conductive post 134-6 disposed on an upper surface of the first conductive pattern 125 and protruding from an upper surface of the first solder resist layer 141.

The edge of the upper surface of the first conductive pattern 125 may be positioned to be lower than the upper surface of the insulating layer 112. The conductive post 134-6 may be formed based on a portion of the first conductive layer 132 and a thickness difference or shape difference between the plurality of first conductive patterns 125 may be reduced, so that the occurrence of an electrical short between the conductive post 134-6 and the adjacent conductive structure may be suppressed.

For example, when the first conductive layer 132 of FIG. 1I is etched, a side surface of the conductive posts 134 may also be etched finely, so that the edge portion of the upper surface of the first conductive pattern 125 may be etched when the upper portion of the second conductive pattern 127 is etched. Alternatively, since a horizontal size of the etch stop pattern 133 of FIG. 1J may be smaller than a horizontal size of the first conductive pattern 125, the edge portion of the upper surface of the first conductive pattern 125 may be etched together when the upper portion of the second conductive pattern 127 is etched.

Accordingly, a width W3 of the lower surface of the conductive post 134-6 may be less than the width (W1 in FIG. 1N) of the upper surface of the first conductive pattern 125, or a width W4 of the upper surface of the conductive post 134-6 may be less than the width W3 of the lower surface of the conductive post 134-6, but is not limited thereto.

For example, a portion of a side surface of the conductive post 134-6 may contact the first solder resist layer 141. Accordingly, a portion of the first solder resist layer 141 may be disposed in close contact with the edge of the upper surface of the first conductive pattern 125, and structural stability of the conductive posts 134-6 may be improved.

For example, the first conductive pattern 125 may be connected to an upper surface of the conductive via 123, and the third conductive pattern 121 may be connected to a lower surface of the conductive via 123. A width of the surface (e.g., the upper surface) of the conductive via 123 connected to the first conductive pattern 125 is less than a width of the surface (e.g., the lower surface) of the conductive via 123 connected to the third conductive pattern 121. For example, a width difference in the conductive via 123 may be formed in the process of drilling a portion of the insulating layer 112 (a portion in which the conductive via is formed). Since the first conductive pattern 125 may receive an electrical connection path through the conductive via 123 and the third conductive pattern 121, the second conductive pattern 127 may be omitted according to design.

Referring to FIGS. 1N and 7, a distance D3 between the first and second conductive patterns 125 and 127 may be less than the width W1 of the first conductive pattern 125, and the width W1 of the first conductive pattern may be greater than the width W2 of the second conductive pattern 127. Since each of the distance D3 and the width W2 may be short, the degree of integration of the electrical connection path of the PCB 100n according to an exemplary embodiment in the present disclosure may increase.

When the number of the first conductive patterns 125 is plural, the width W1 may be measured as an average of widths W1-1 and W1-2 of the plurality of first conductive patterns 125. When the number of the second conductive patterns 127 is plural, the width W2 may be measured as an average of the widths W2-1 and W2-2 of each of the plurality of second conductive patterns 127. When at least one of the first and second conductive patterns 125 and 127 is plural, the distance D3 may be measured as an average of the plurality of intervals D3-1, D3-2, and D3-3.

For example, the first conductive pattern 125 may be a pad or a land, and the second conductive pattern 127 may be a wiring. The width W2 of the second conductive pattern 127 may be an average of width measurement values in a direction perpendicular to the extension direction at each point of the wiring in the extension direction. The width W1 of the first conductive pattern 125 may be measured in a straight line passing through the center of the first conductive pattern 125, and may be measured in a direction perpendicular to a direction of a long side measured in the straight line. The distance D3 may also be measured in the same direction as that of the widths W1 and W2, and may be measured as an averaged value.

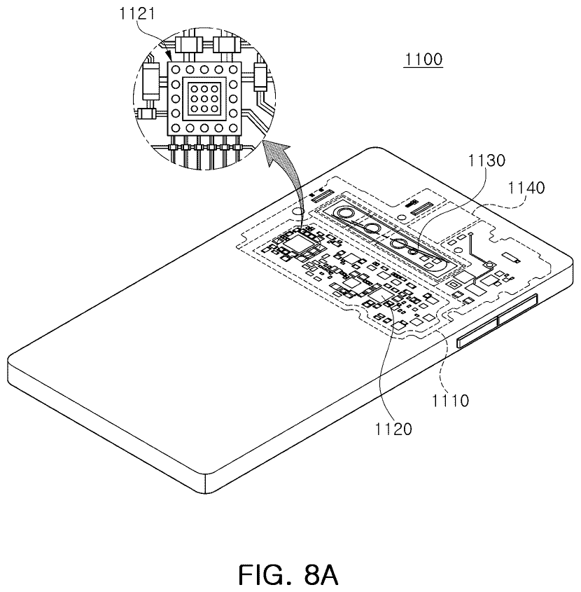

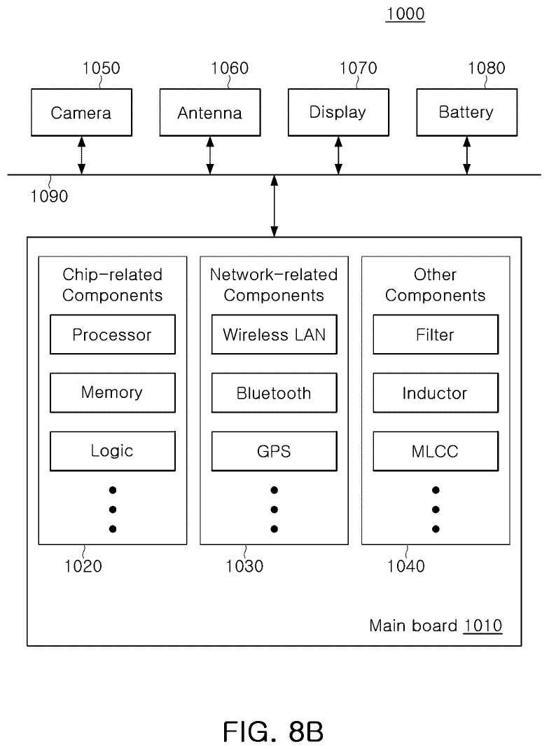

FIG. 8A is a diagram illustrating a structure of an electronic device in which a PCB may be disposed according to an exemplary embodiment in the present disclosure, and FIG. 8B is an electronic device in which a PCB according to an exemplary embodiment in the present disclosure may be disposed.

Referring to FIGS. 8A and 8B, the electronic device 1000 may accommodate a main board 1010. A chip-related component 1020, a network-related component 1030, and other components 1040 may be physically and/or electrically connected to the main board 1010. These may be combined with other electronic components to be described later to form various signal lines 1090.

The chip-related component 1020 includes a memory chip, such as a volatile memory (e.g., DRAM), a non-volatile memory (e.g., ROM), and a flash memory; application processor chips, such as a central processing unit (CPU), a graphics processing unit (GPU), a digital signal processor, an encryption processor, a microprocessor, and a microcontroller; logic chips, such as analog-to-digital converters (ADCs) and application-specific integrated chips (ASICs), but is not limited thereto, and may include other types of chip-related electronic components. Also, of course, these chip-related components 1020 may be combined with each other. The chip-related component 1020 may be in the form of a package including the chips or electronic components described above.

The network-related components 1030 include Wi-Fi (IEEE 802.11 family, etc.), WiMAX (IEEE 802.16 family, etc.), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G, 5G and any other wireless and wired protocols designated thereafter, and but the present disclosure is not limited thereto and may include any other wireless or wired protocols and certain protocols. Also, the network-related component 1030 may be combined with the chip-related component 1020.

The other components 1040 may include a high frequency inductor, a ferrite inductor, a power inductor, ferrite beads, low temperature co-firing ceramics (LTCC), an electro-magnetic interference (EMI) filter, a multilayer ceramic condenser (MLCC), and the like. However, the present disclosure is not limited thereto and may include a passive element in the form of a chip component used for various other purposes in addition thereto. In addition, the other component 1040 may be combined with the chip-related component 1020 and/or the network-related component 1030.

Depending on the type of the electronic device 1000, the electronic device 1000 may include other electronic components that may or may not be physically and/or electrically connected to the main board 1010. Examples of other electronic components include a camera module 1050, an antenna module 1060, a display 1070, and a battery 1080. However, the present disclosure is not limited thereto, and the other electronic component may include an audio codec, a video codec, a power amplifier, a compass, an accelerometer, a gyroscope, a speaker, a mass storage device (e.g., a hard disk drive), a compact disk (CD), a digital versatile disk (DVD), etc. In addition to this, other electronic components used for various purposes may be included depending on the type of the electronic device 1000.

The electronic device 1000 may be a smart phone, a personal digital assistant, a digital video camera, a digital still camera, a network system, a computer, a monitor, a tablet, a laptop, a netbook, a television, a video game player, a smart watch, an automotive, and the like. However, the present disclosure is not limited thereto and may be any other electronic device that processes data in addition thereto.

The electronic device may be, for example, a smartphone 1100. A motherboard 1110 is accommodated inside the smartphone 1100, and various components 1120 are physically and/or electrically connected to the motherboard 1110. Also, other components that may or may not be physically and/or electrically connected to the motherboard 1110, such as a camera module 1130 and/or a speaker 1140, may be accommodated therein. A portion of the component 1120 may be the chip-related component described above, for example, a component package 1121, but is not limited thereto. The component package 1121 may be in the form of a PCB on which electronic components including active components and/or passive components are surface-mounted. Alternatively, the component package 1121 may be in the form of a PCB in which active and/or passive components are embedded. Meanwhile, the electronic device is not necessarily limited to the smartphone 1100, and of course, may be other electronic devices as described above.

The PCB and the method for manufacturing a PCB according to an exemplary embodiment in the present disclosure may efficiently increase the degree of integration and/or reliability of an electrical connection path that may be provided, and suppress an increase in the incidence of defects (e.g., an electrical short) due to the increased degree of integration.

While exemplary embodiments have been illustrated and described above, it will be apparent to those skilled in the art that modifications and variations could be made without departing from the scope of the present disclosure as defined by the appended claims.

What is claimed is:

1. A printed circuit board (PCB) comprising:
an insulating layer;
a first solder resist layer disposed on an upper surface of the insulating layer;
a first conductive pattern disposed on the insulating layer and providing a conductive post protruding from an upper surface of the first solder resist layer; and
a second conductive pattern buried in the insulating layer and having an upper surface positioned to be lower than the upper surface of the insulating layer.

2. The PCB of claim 1, further comprising:
a conductive via connected to the first conductive pattern; and
a third conductive pattern connected to the conductive via and disposed below the insulating layer,
wherein a width of a surface of the conductive via connected to the first conductive pattern is less than a width of a surface of the conductive via connected to the third conductive pattern.

3. The PCB of claim 1, further comprising:
a second solder resist layer disposed below the insulating layer,
wherein a thickness of the first solder resist layer is thinner than a thickness of the second solder resist layer.

4. The PCB of claim 1, wherein
the first solder resist layer includes an opening in which the conductive post is disposed, and
a portion of a side surface of the conductive post is in contact with the first solder resist layer.

5. The PCB of claim 1, wherein
the insulating layer includes a recessed portion, and
a portion of the first solder resist layer and the second conductive pattern contact each other in the recessed portion.

6. The PCB of claim 1, wherein a distance between the first and second conductive patterns is less than a width of the first conductive pattern.

7. The PCB of claim 1, wherein a width of the first conductive pattern is greater than a width of the second conductive pattern.

8. The PCB of claim 1, further comprising a semiconductor chip connected to the conductive post in a flip-chip structure.

9. The PCB of claim 1, wherein a width of an upper surface of the conductive post is less than a width of a lower surface of the conductive post.

10. A printed circuit board (PCB) comprising:
an insulating layer;
a first solder resist layer disposed on an upper surface of the insulating layer;
a first conductive pattern buried in the insulating layer; and
a conductive post disposed on an upper surface of the first conductive pattern and protruding from an upper surface of the first solder resist layer,
wherein an edge of the upper surface of the first conductive pattern is positioned to be lower than the upper surface of the insulating layer.

11. The PCB of claim 10, wherein a width of a lower surface of the conductive post is less than a width of the upper surface of the first conductive pattern.

12. The PCB of claim 10, wherein a width of an upper surface of the conductive post is less than a width of a lower surface of the conductive post.

13. The PCB of claim 10, further comprising:
a conductive via having an upper surface connected to the first conductive pattern; and
a third conductive pattern connected to the conductive via and disposed below the insulating layer,
wherein a width of a surface of the conductive via connected to the first conductive pattern is less than a width of a surface of the conductive via connected to the third conductive pattern.

14. The PCB of claim 10, further comprising:
a second solder resist layer disposed below the insulating layer,
wherein a thickness of the first solder resist layer is thinner than a thickness of the second solder resist layer.

15. The PCB of claim 10, wherein
the first solder resist layer includes an opening in which the conductive post is disposed, and
a portion of a side surface of the conductive post is in contact with the first solder resist layer.

16. A method for manufacturing a printed circuit board (PCB), the method comprising:
forming first and second conductive patterns on a first conductive layer on a base insulating layer;
forming an insulating layer on the first and second conductive patterns;
separating the base insulating layer from at least a portion of the first conductive layer;
etching a partial region of at least a portion of the first conductive layer to form a conductive post;
forming a first solder resist layer on a surface of the insulating layer on which the conductive post is formed; and
etching a portion of the first solder resist layer to reduce a thickness of the first solder resist layer.

17. The method of claim 16, wherein
between the forming of the first solder resist layer and the etching of the portion of the first solder resist layer, an upper surface of the first solder resist layer is located to be higher than an upper surface of the conductive post, and
after the etching of the portion of the first solder resist layer, an upper surface of the etched first solder resist layer is positioned to be lower than the upper surface of the conductive post.

18. The method of claim 16, wherein
the forming of the first solder resist layer includes forming the first solder resist layer and the second solder resist layer on upper and lower surfaces of the insulating layer, respectively; and
the etching of the portion of the first solder resist layer includes etching a portion of the first solder resist layer to increase a thickness difference between the first solder resist layer and the second solder resist layer.

19. The method of claim 16, wherein
a partial region of at least a portion of the first conductive layer overlaps the second conductive pattern in a vertical direction, and
the forming of the first solder resist layer includes forming the first solder resist layer so that the first solder resist layer contacts the second conductive pattern.

20. The method of claim 16, further comprising:
forming an etch stop pattern in a region of the first conductive layer overlapping the first conductive pattern between the separating and the forming of the conductive post; and
removing the etch stop pattern between the forming of the conductive post and the forming of the first solder resist layer,
wherein the etch stop pattern includes at least one of nickel (Ni) and tin (Sn).

21. A printed circuit board (PCB) comprising:
an insulating layer;
a first conductive pattern buried in the insulating layer;
a second conductive pattern buried in the insulating layer and having an upper surface positioned to be lower than an upper surface of the insulating layer;
a first solder resist layer disposed on the insulating layer to cover the second conductive pattern; and
a conductive post extending from the first conductive pattern to protrude from an upper surface of the first solder resist layer.

22. The PCB of claim 21, wherein the conductive post and the first conductive pattern include a same material.

23. The PCB of claim 21, wherein the first conductive pattern and the second conductive pattern are buried in the insulating layer at substantially a same depth.

24. The PCB of claim 21, wherein a side surface of the first conductive pattern and a side surface of the conductive post are offset from each other.

25. The PCB of claim 21, wherein a side surface of the conductive post has a substantially constant slope with respect to the upper surface of the insulating layer.

26. The PCB of claim 21, further comprising:
a conductive via connected to the first conductive pattern; and
a third conductive pattern connected to the conductive via and disposed below the insulating layer,
wherein a width of a surface of the conductive via connected to the first conductive pattern is less than a width of a surface of the conductive via connected to the third conductive pattern.

27. The PCB of claim 21, further comprising:
a second solder resist layer disposed below the insulating layer,
wherein a thickness of the first solder resist layer is thinner than a thickness of the second solder resist layer.

28. The PCB of claim 21, wherein
the first solder resist layer includes an opening in which the conductive post is disposed, and
a portion of a side surface of the conductive post is in contact with the first solder resist layer.

29. The PCB of claim 21, wherein
the first solder resist layer includes an opening in which the conductive post is disposed, and
the first solder resist layer is spaced apart from the conductive post.
